(19) United States
(12) Patent Application Publication
(10) Pub. No.: US 2008/0185596 A1
(43) Pub. Date: Aug. 7, 2008

(54) SYSTEM FOR DISPLAYING IMAGES

(75) Inventors: Chang-Ho Tseng, Taoyuan County (TW); Yu-Chun Shih, Taichung City (TW); Hsuan-Chih Huang, Chiayi County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: TPO DISPLAYS CORP., Miao-Li County (TW)

(21) Appl. No.: 11/670,582

(22) Filed: Feb. 2, 2007

(51) Int. Cl. H01L 31/12; H01L 33/00

(52) U.S. Cl. 257/84; 257/E33.077; 257/E31.095

(57) ABSTRACT

Embodiments of a system for displaying images include a light emitting device with a plurality of photo sensors. Each photo sensor includes a PIN diode composed of an N⁺ doped semiconductor region, a P⁺ doped semiconductor region, and an intrinsic semiconductor region formed therebetween. An insulated control gate overlaps the intrinsic semiconductor region and is operative to provide the PIN diode with a controllable electric characteristic with respect to a saturation photo current at a saturation voltage.

### BACKGROUND OF THE INVENTION

1. Field of the Invention

The invention relates to a system for displaying images. More particularly, the invention relates to a system for displaying images with photo sensors.

2. Description of the Related Art

Flat display systems are broadly applied to portable electronic apparatuses, such as notebooks and personal digital assistants (PDAs), due to thin profile and low power consumption. As the requirements of high quality display increase, flat panels with high quality and low price are required. In the display system, a photo sensor employing a PIN diode is a significant element. Thus, development of the photo sensor is an important goal.

### BRIEF SUMMARY OF THE INVENTION

To achieve these and other advantages and in accordance with the purpose of the invention, as embodied and broadly described herein, the invention provides a system of displaying images providing PIN diodes with controllable electric characteristics. A detailed description is given in the following embodiments with reference to the accompanying drawings.

An embodiment of a system for displaying images comprises a light emitting device with a plurality of photo sensors. Each photo sensor comprises a PIN diode comprising an N⁺ doped semiconductor region, a P⁺ doped semiconductor region, and an intrinsic semiconductor region formed therebetween. An insulated control gate overlaps the intrinsic semiconductor region and is operative to provide the PIN diode with a controllable electric characteristic with respect to a saturation photo current at a saturation voltage.

### BRIEF DESCRIPTION OF THE DRAWINGS

The invention can be more fully understood by reading the subsequent detailed description and examples with references made to the accompanying drawings, wherein:

FIG. 1 is a schematic illustration of a conventional PIN diode for photo sensing.

FIGS. 2A-2C are cross section views of an exemplary embodiment of a method for manufacturing a photo sensor.

FIG. 2D is a cross section view of another exemplary embodiment of a photo sensor.

FIG. 3 shows a PIN diode with metal gate thereon according to an exemplary embodiment of the system for displaying images.

FIG. 4A is a graph showing electric characteristics of sixteen PIN diodes without control gates.

FIG. 4B is a graph showing electric characteristics of sixteen PIN diodes with control gates.

FIG. 5 is a plan view of an embodiment of a system for displaying images.

### DETAILED DESCRIPTION OF THE INVENTION

The following description is of the best-contemplated mode of carrying out the invention. This description is made for the purpose of illustrating the general principles of the invention and should not be taken in a limiting sense. Although the invention is described with respect to a specific embodiment, the principles of the invention, as defined by the claims appended herein, can obviously be applied beyond the specifically described embodiments of the invention described herein.

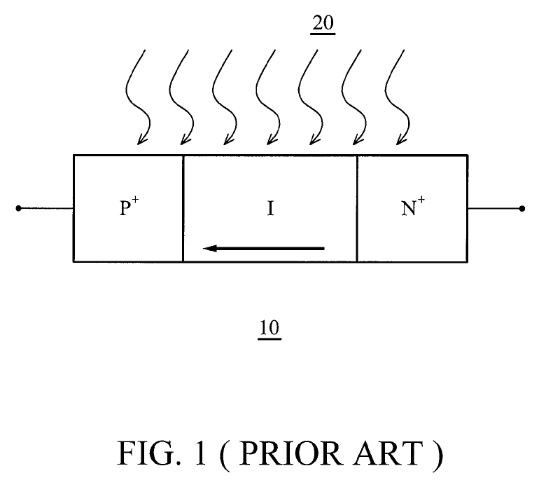

FIG. 1 shows a schematic illustration of a conventional PIN diode 10 for photo sensing, in which an intrinsic (I) region generates photons on receipt of incident light 20.

Typically, conventional PIN diode 10 may be formed using a low temperature polysilicon process (LTPS). An unrecognized problem is diodes made by a same LTPS process generally having different electric characteristics with respect to a saturation photo leakage current at a saturation voltage, which however, will cause a uniformity issue of light intensity measurement in systems for displaying images according to the applicant's investigation.

To improve the problem, a photo sensor comprising a PIN diode with an insulated control gate overlapping an intrinsic semiconductor region thereof is disclosed, in which the insulated control gate is operative to provide the PIN diode with a controllable electric characteristic with respect to a saturation photo leakage current at a saturation voltage.

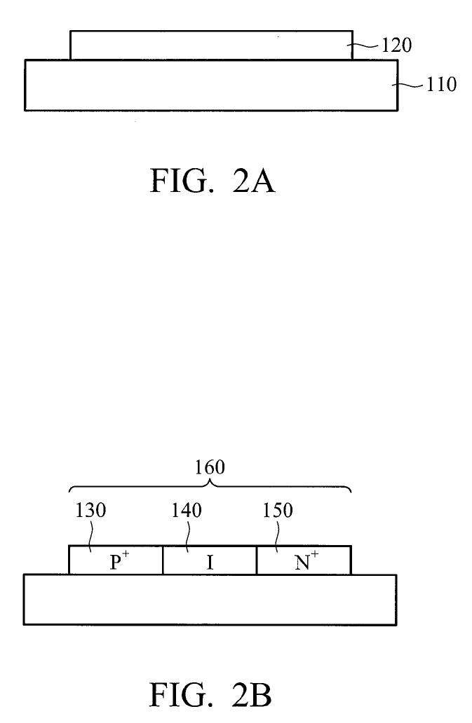

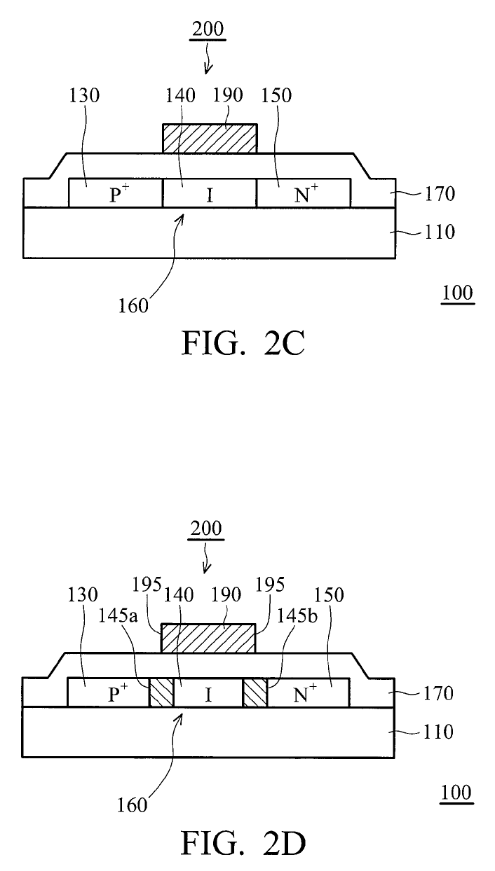

Exemplary embodiments of a photo sensor and fabrication methods for the same will now be described. FIG. 2C shows a cross section view of an embodiment of a photo sensor 100, comprising a PIN diode. FIG. 2A to 2C illustrate a method for manufacturing a photo sensor.

Referring to FIG. 2C, an embodiment of a photo sensor 100 is provided. In this case, a PIN diode 160, such as a low temperature poly silicon diode, laterally formed on a substrate 110, comprises an N type doped semiconductor region such as highly doped N⁺ region 150, a P⁺ doped semiconductor region 130 such as highly doped P⁺ region, and an intrinsic semiconductor region 140 formed therebetween. Further, a feature of an insulated control gate 200, overlapping the intrinsic semiconductor region 140 (I), is operative to provide the PIN diode 160 with a controllable electric characteristic with respect to a saturation photo leakage current at a saturation voltage. The insulated control gate 200 comprises a gate insulation layer 170 to cover the PIN diode 160 and a control gate 190 formed on the gate insulation layer 170 opposite the intrinsic semiconductor region 140. In some embodiments, the control gate 190 is rectangular or trapezoid. Further, in this case, the insulated control gate 200 may be a bottom gate underlying the PIN diode or a top gate overlying the PIN diode.

The process of forming photo sensor 100 will now be described in detail.

FIG. 2A shows substrate 110 which may be a transparent insulation plate, such as glass substrate, on which a semiconductor layer 120 is formed. The semiconductor layer 120 may comprise polysilicon. For example, an amorphous silicon layer is first formed by deposition such as chemical vapor deposition and then crystallized or annealed with excimer laser, ELA to form a polysilicon layer, which can be defined by conventional lithography and etched to form a predetermined diode pattern over the substrate 110.

Turing now to FIG. 2B, a PIN diode 160 is laterally disposed on the substrate 110. In this step, the semiconductor layer 120 can be doped with different impurities in different regions to form the PIN diode. For example, the PIN diode 160 is semiconductor diode comprising an intermediate region 140 between a P⁺ doped region 130 and an N⁺ doped region 150, doped much less than the P⁺ doped region 130 and the N⁺ doped region 150, also referred to as an intrinsic region or I region.

Typically, the P region 130 and the N region 150 are highly doped and can be formed locally in the semiconductor layer, such as polysilicon layer by ion implantation and/or diffusion. The intrinsic region 140 is masked during these doping processes so as to retain its intrinsic conductivity.

Thereafter, as shown in FIG. 2C, the PIN diode 160 and the exposed substrate 110 are covered with gate insulation layer 170 which may be of silicon oxide or silicon nitride. A conductive layer, such as metal layer, ITO layer or doped polysilion layer, is preferably formed on the gate insulation layer 170, and then patterned to form a control gate 190. In one example, the width of control gate 190 can be approximately equal to that of intrinsic region 140. Thus, the above described doping process may be carried out after forming the control gate formation, since it can be advantageous to use the control gate 190 as a mask for self-aligned doping process.

FIG. 2D shows a modification of the PIN diode 160. In this modification, lightly doped regions, such as a P type lightly doped region 145a and a N type lightly doped region 145b are respectively formed in the P⁺ doped semiconductor region 130 and N⁺ doped semiconductor region 150, both neighboring the intrinsic region 140. Specifically, edges of the P type lightly doped region 145a and the N type lightly doped region 145b, neighboring the intrinsic region 140, further align with the both edges 195 of the control gate 190. In an preferable alternative embodiment, the control gate 190 can be extended to completely cover or cover at least a portion of the P-type lightly doped region 145a and the N-type lightly doped region 145b thereby increasing a processing tolerance for misalignment between the control gate 190 and the intrinsic region 140.

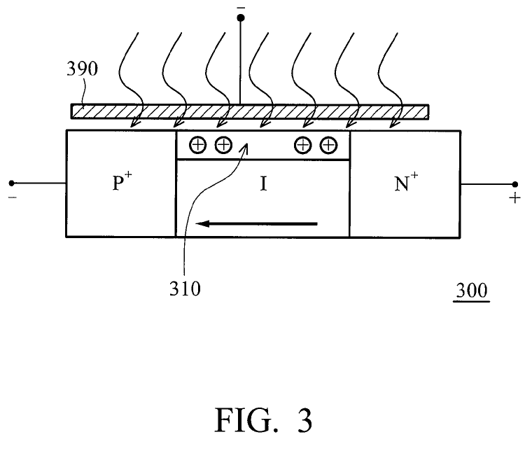

Referring to FIG. 3, a PIN diode with metal gate thereon according to an exemplary embodiment of the system for displaying images is shown. In one example, a preferred PIN diode 300 formed by low temperature poly silicon process can be employed in an active-matrix OLED display or a LCD display with the same low temperature poly silicon process. The PIN diode 300 for photo sensing comprises an N⁺ doped semiconductor region, a P doped semiconductor region and an intrinsic semiconductor region (I) formed therebetween. Further, a low resistance and fixed channel region 310 in the intrinsic semiconductor region (I) is induced by applying an appropriate control voltage to a control gate 390 for providing a photo current with stationary transportation. Thus, a feature in this embodiment is that the control metal gate 390, overlapping the intrinsic semiconductor region (I) and extending to partially cover the N⁺ doped semiconductor region and the P⁺ doped semiconductor region, can be operative under a control voltage to confine the PIN diode 300 with a specified electric characteristic with respect to a saturation photo leakage current at a saturation voltage.

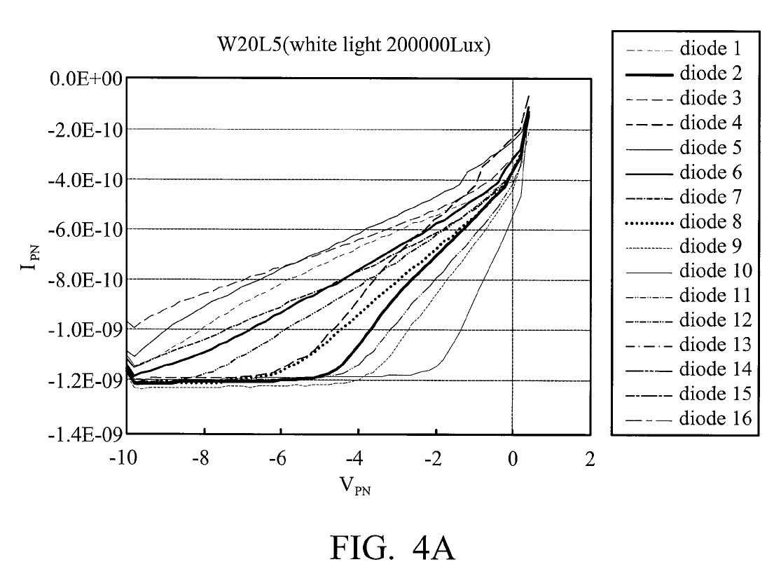

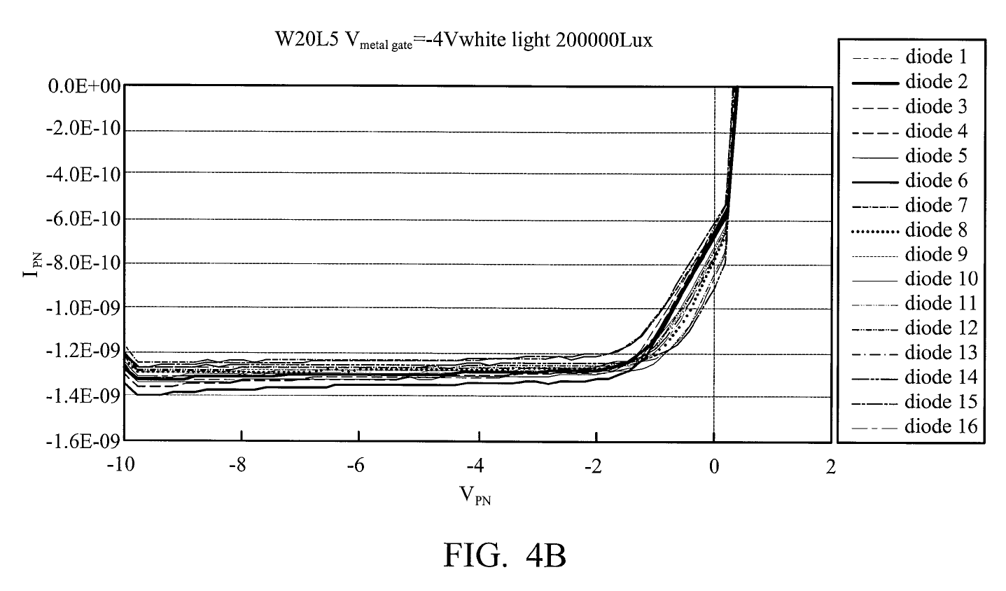

FIG. 4A is a graph showing electric characteristics of sixteen PIN diodes without control gate, made using the same LTPS process, where the width/length ratio of the intrinsic semiconductor region (I) is 20/5 and the sixteen PIN diodes are exposed with white light illumination of about 200,000 lux. According to the electric characteristics with respect to a saturation photo leakage current (I_{PN}) at a saturation voltage (V_{PN}), as each diode has different electric characteristic, clearly, saturation photo leakage currents of the sixteen PIN diodes are not uniform.

FIG. 4B is a graph showing electric characteristics of sixteen PIN diodes with control gates, made using the same LTPS process, where the width/length ratio of the intrinsic semiconductor region (I) is 20/5, the applied control gate voltage is −4V, and the sixteen PIN diodes are exposed with white light illumination of about 200,000 lux. According to the electric characteristics with respect to a saturation photo leakage current (I_{PN}) at a saturation voltage (V_{PN}), as the diodes have uniform electric characteristic, saturation photo leakage currents of the sixteen PIN diodes are thus sufficiently uniform.

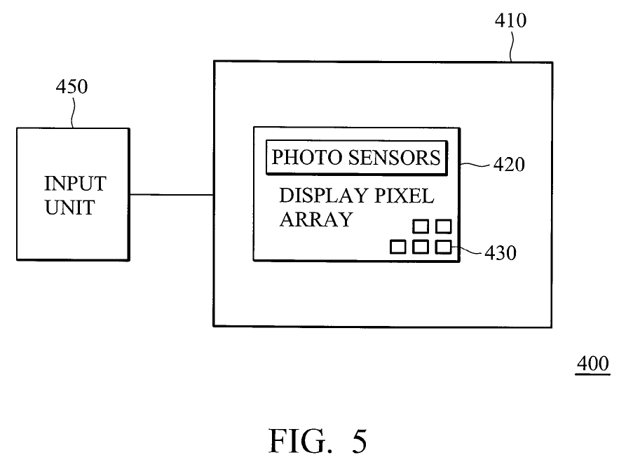

As shown in FIG. 5, the display panel 410 comprises a light emitting device 420, such as an active matrix organic electroluminescent device or active matrix LCD device, with photo sensors. Generally, the light emitting device 420 comprises a display pixel array having an array of light emitting pixels 430. Specifically, the photo sensors comprise PIN diodes with insulated control gates such as the PIN diodes 100 shown in FIG. 2C and FIG. 2D, in which the PIN diodes are optically coupled to the light emitting pixels 430 to detect light emitted therefrom generating photo leakage currents. In a preferred embodiment, the insulated control gates are operative under corresponding control voltages respectively to provide the PIN diodes with a substantially uniform electric characteristic with respect to a saturation photo leakage current at a saturation voltage. Further, the display panel 410 can form a portion of a variety of electronic devices (in this case, electronic device 400). Generally, the electronic device 400 can comprise the display panel 410 and an input unit 450. Further, the input unit 450 is operatively coupled to the display panel 410 and provides input signals (e.g., an image signal) to the display panel 410 to generate images. The electronic device 400 can be a mobile phone, digital camera, PDA (personal data assistant), notebook computer, desktop computer, television, car display, or portable DVD player, for example.

While the invention has been described by way of example and in terms of preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
a light emitting device with a plurality of photo sensors, each photo sensor comprising:
a PIN diode, comprising an N type doped semiconductor region, a P type doped semiconductor region, and an intrinsic semiconductor region formed therebetween; and
an insulated control gate overlapping the intrinsic semiconductor region,
wherein the insulated control gate is operative to provide the PIN diode with a controllable electric characteristic with respect to a saturation photo current at a saturation voltage.

2. The system as claimed in claim 1, wherein the light emitting device comprises a display pixel array with a plurality of light emitting pixels in which the PIN diodes are optically coupled to the light emitting pixels to detect light emitted therefrom generating photo currents.

3. The system as claimed in claim 2, wherein the insulated control gates are operative to provide the PIN diodes with a substantially uniform electric characteristic with respect to a saturation photo current at a saturation voltage.

4. The system as claimed in claim 1, wherein the N type doped semiconductor region or the P type doped semiconductor region further comprise a lightly doped region neighboring the intrinsic semiconductor region.

5. The system as claimed in claim 4, wherein the insulated control gate is extended to cover at least a portion of the lightly doped region.

6. The system as claimed in claim 4, wherein an edge of the lightly doped region, neighboring the intrinsic semiconductor region, aligns with an edge of the insulated control gate.

7. The system as claimed in claim 1, wherein the N type doped semiconductor region further comprise a N type lightly doped region neighboring the intrinsic semiconductor region and the P type doped semiconductor region further comprise a P type lightly doped region neighboring the intrinsic semiconductor region.

8. The system as claimed in claim 1, wherein the insulated control gate comprises a metal gate layer, a polysilicon gate layer or an ITO gate layer.

9. The system as claimed in claim 1, wherein the insulated control gate is a top gate overlying the PIN diode.

10. The system as claimed in claim 1, wherein the insulated control gate is a bottom gate underlying the PIN diode.

11. The system as claimed in claim 1, wherein the PIN diode is a low temperature poly silicon diode.

12. The system as claimed in claim 2, further comprising a display panel, wherein the light-emitting device forms a portion of the display panel.

13. The system as claimed in claim 12, further comprising an electronic
device, wherein the electronic device comprises:
the display panel; and
a controller coupled to the display panel and operative to provide input to the display panel such that the display panel displays images.

14. The system as claimed in claim 13, wherein the electronic device is a mobile phone, digital camera, PDA (personal data assistant), notebook computer, desktop computer, television, car display, or portable DVD player.
